(19) United States
(12) Patent Application Publication
(10) Pub. No.: US 2009/0154215 A1
(43) Pub. Date: Jun. 18, 2009

(54) REDUCING NOISE AND DISTURBANCE BETWEEN MEMORY STORAGE ELEMENTS USING ANGLED WORDLINES

(75) Inventors: Suketu Parikh, San Jose, CA (US); Vidyut Gopal, Sunnyvale, CA (US); Brad Davis, Mountain View, CA (US)

Correspondence Address: AMIN, TUROCY & CALVIN, LLP, 127 Public Square, 57th Floor, Key Tower, CLEVELAND, OH, 44114, US

(73) Assignee: SPANSION LLC, Sunnyvale, CA (US)

(21) Appl. No.: 11/957,028

(22) Filed: Dec. 14, 2007

(51) Int. Cl. G11C 5/06; G11C 5/02

(52) U.S. Cl. 365/63; 365/51

(57) ABSTRACT

Devices and/or methods that facilitate reducing cross-talk noise and/or complementary bit disturb between adjacent storage elements in a memory device are presented. A memory device includes a memory array with wordlines formed in a zig-zag pattern such that each wordline can have segments that are parallel to the x-axis and other segments that are angled from a direction parallel to the x-axis based in part on a predetermined angle. Adjacent storage elements can be positioned at respective ends of an angled segment of a wordline to facilitate increasing the distance between such storage elements, as compared to the distance between storage elements associated with an orthogonal memory array, where the increase in distance can be based in part on the predetermined angle. The size of the memory array can be the same or substantially the same size, as compared to an orthogonal memory array.

### TECHNICAL FIELD

The subject innovation relates generally to memory devices and in particular to devices and methods that facilitate reducing cross-talk noise between memory storage elements.

### BACKGROUND

A wide variety of memory devices can be used to maintain and store data and instructions for various computers and similar systems. In particular, flash memory is a type of electronic memory media that can be rewritten and that can retain content without consumption of power. Flash memory devices typically are less expensive and denser as compared to many other memory devices, meaning that flash memory devices can store more data per unit area. Flash memory has become popular, at least in part, because it combines the advantages of the high density and low cost of erasable programmable read only memory (EPROM) with the electrical erasability of electrically erasable programmable read only memory (EEPROM). It can be used in many portable electronic products, such as cell phones, portable computers, voice recorders, thumbnail drives and the like, as well as in many larger electronic systems, such as cars, planes, industrial control systems, etc. The fact that flash memory can be rewritten, as well as its retention of data without a power source, small size, and light weight, have all combined to make flash memory devices useful and popular means for transporting and maintaining data.

Conventionally, many types of memory devices, such as flash memory, EPROM, and EEPROM, can comprise a memory array that includes a plurality of memory cells that are structured in an orthogonal array of crossing (e.g., intersecting) wordlines and bitlines, where the bitlines can be perpendicular to the wordlines, and where storage elements (e.g., of the memory cell) can be at or near the point of crossing of respective wordlines and bitlines in the memory array. Selection of particular wordline(s) and bitline(s) associated with a memory cell by application of respective voltages can facilitate access of the memory cell and the storage element(s) therein.

To increase storage capability while maintaining the same or smaller package size, memory devices are becoming increasingly more and more dense, and as a result, storage elements are being placed closer and closer to each other in the memory array. As storage elements are moved closer together in the array, there can be an increase in cross-talk noise between the storage elements and/or other noise or disturbance (e.g., complementary bit disturb) due to close proximity of the storage elements to each other. The cross-talk noise can negatively impact the performance of the memory device, as, for example, programming of storage elements can be negatively impacted and/or data stored in a storage element can be disturbed due to an operation being performed on a nearby storage element.

It is desirable to be able to reduce cross-talk and/or complementary bit disturb between memory storage elements in a memory array of a memory device, for example, by increasing the distance between storage elements in the memory array. Further, it is desirable to maintain the same or similar size of the memory array and/or memory device.

### SUMMARY

The following presents a simplified summary of the innovation in order to provide a basic understanding of some aspects described herein. This summary is not an extensive overview of the disclosed subject matter. It is intended to neither identify key or critical elements of the disclosed subject matter nor delineate the scope of the subject innovation. Its sole purpose is to present some concepts of the disclosed subject matter in a simplified form as a prelude to the more detailed description that is presented later.

The disclosed subject matter relates to memory devices and/or methods that can facilitate reducing cross-talk noise between storage elements in a memory array of the memory device. A memory device can comprise a memory array that can contain a plurality of memory cells that can facilitate storage of data. Each memory cell can contain one or more storage elements, and one or more bits of data can be stored in each storage element. The memory array can comprise a plurality of wordlines and bitlines that can be respectively associated with respective memory cells, such that a storage element of a memory cell can be located where a respective wordline and bitline intersect.

In one embodiment, the wordlines (WLs) can be structured such that the WLs are angled at predetermined points, instead of being in a straight line extending across the memory array, as each WL can be angled at a predetermined angle (e.g., an angle between 0 and 90 degrees, or an angle between 0 and −90 degrees) at respective points where a storage element and an adjacent storage element are located, so that the distance between the two adjacent storage elements can be increased based in part on the predetermined angle, as compared to the distance between two storage elements in a conventional memory device with a straight WL associated with a straight bitline (BL) in an orthogonal array, for example. The amount of increase in distance between the two storage elements can be based in part on the angle of the angled portion (e.g., segment) of the WL with respect to the portion of the WL from which it angles and/or the storage element at the point where the WL angles.

In one embodiment, two adjacent storage elements can be respectively associated with two adjacent memory cells along the same WL. A segment(s) of the WL can angle from its original path (e.g., a path parallel to the x-axis) at a predetermined angle, as compared to its previous path, at or near the point of a first storage element of the first memory cell and the WL can proceed at that angle until it reaches a point at or near another storage element adjacent to the first storage element, where the other storage element can be in another memory cell. At or substantially near the point the WL segment, as angled, meets the adjacent storage element, the WL can de-angle from the predetermine angle so that it is on a path line that is similar to and/or along a parallel path line as the original path before the angling (e.g. the WL path can de-angle so that it is on a path that is parallel or substantially parallel to the x-axis). The WL can proceed to the next storage element, and at or substantially near the next storage element, the WL can angle at another predetermined angle, but where the WL can angle in the opposite direction as the first predetermined angle (e.g. where one segment of the WL can be angled at a positive angle based on the x-axis and another segment of the WL can be angled at a negative angle based on the x-axis). The WL can proceed to the following adjacent storage element, and at or near the following adjacent storage element, the WL can de-angle to proceed along the path line of the original path (e.g., a path parallel to the x-axis). The WL can proceed in such a zig-zag fashion until the WL reaches the end of that portion of the memory array. Each WL in the memory array can be the same or substantially similar and respective angled portions of the respective WLs can be parallel to each other so that the WLs can be the same or substantially the same distance apart from each other as the respective zig-zagging WLs extend across the memory array.

In another embodiment, the predetermined angle of the portion(s) of the WL that angles can be 45 degrees, where the distance d between two adjacent storage elements of respective adjacent memory cells along a WL can be x*square root 2, where x can be the amount of space between two such adjacent storage elements in a conventional memory array (e.g. an orthogonal array of WLs and BLs). In one aspect, the subject innovation, in part by increasing the distance between two adjacent storage elements associated with the portion of the WL that is angled, can decrease the amount of cross-talk noise between such adjacent storage elements (e.g., between the two adjacent memory cells), as compared to conventional memory devices, which can improve overall performance of the memory device, while maintaining the same or similar size of the memory device.

In accordance with still another embodiment, the distance between adjacent storage elements of the same memory cell can be increased by a factor (e.g. real number greater than 1), as compared to the distance between storage elements of a conventional memory cell (e.g. memory cell in an orthogonal memory array), based in part on the predetermined angle (e.g., between 0 and 90 degrees, or between 0 and −90 degrees) of the segment of the WL associated with such adjacent storage elements, where such segment of the WL can be angled as compared to the original path line of the WL (e.g., along a path parallel to the x-axis). The WLs of the memory array can be structured in a zig-zag manner across the memory array.

In accordance with an aspect of the disclosed subject matter, each memory array can comprise a plurality of sectors each containing a respective plurality of memory cells respectively associated with respective WLs and BLs. The WLs, with respective segments of the WLs angled in a zig-zag manner, can be structured so that the WLs, including the bottom WL, of a first sector can be parallel and/or substantially parallel (including at angled segments of the respective WLs) to the WLs, including the top WL, of the adjacent sector situated under the first sector.

In accordance with still another aspect, methods that can facilitate reducing cross-talk noise and/or complementary bit disturb between storage elements in a memory array of a memory device are presented. In another aspect, electronic devices that can comprise a memory device that can contain a memory array structured to reduce cross-talk noise and/or complementary bit disturb between storage elements, in accordance with the disclosed subject matter, are presented.

The following description and the annexed drawings set forth in detail certain illustrative aspects of the disclosed subject matter. These aspects are indicative, however, of but a few of the various ways in which the principles of the innovation may be employed and the disclosed subject matter is intended to include all such aspects and their equivalents. Other advantages and distinctive features of the disclosed subject matter will become apparent from the following detailed description of the innovation when considered in conjunction with the drawings.

### BRIEF DESCRIPTION OF THE DRAWINGS

FIG. 1 illustrates a diagram of a memory device that can facilitate reducing cross-talk noise to facilitate storage of data in accordance with an embodiment of the subject matter disclosed herein.

FIG. 2a depicts a diagram of memory cells in a portion of a memory array that can facilitate reducing cross-talk noise between storage elements in a memory device in accordance with an aspect of the subject matter disclosed herein.

FIG. 2b depicts a diagram of memory cells in a portion of an orthogonal memory array associated with a memory device.

FIG. 3 illustrates a diagram of a memory device that can facilitate reducing cross-talk noise and/or complementary bit disturb between storage elements to facilitate storage of data in accordance with an embodiment of the disclosed subject matter.

FIG. 4a illustrates a diagram of a memory cell in a portion of a memory array that can facilitate reducing cross-talk noise and/or complementary bit disturb between storage elements in a memory device in accordance with an aspect of the subject matter disclosed herein.

FIG. 4b depicts a diagram of a memory cell in a portion of an orthogonal memory array associated with a memory device

FIG. 5 depicts a diagram of a memory device having multiple sectors that can facilitate storage of data in accordance with an aspect of the disclosed subject matter.

FIG. 6 illustrates a block diagram of a memory device that can facilitate data storage in accordance with an aspect of the disclosed subject matter.

FIG. 7 depicts a methodology that can facilitate reducing cross-talk noise and/or complementary bit disturb to facilitate storing data associated with a memory device in accordance with an aspect of the disclosed subject matter.

FIG. 8 illustrates a methodology that can facilitate reducing cross-talk noise to facilitate storing data associated with a memory device in accordance with an aspect of the disclosed subject matter.

FIG. 9 depicts a methodology that can facilitate reducing cross-talk noise and/or complementary bit disturb to facilitate storing data associated with a memory device in accordance with an aspect of the disclosed subject matter.

FIG. 10 illustrates an example of an electronic device that can be associated with a memory in accordance with an aspect of the disclosed subject matter.

### DETAILED DESCRIPTION

The disclosed subject matter is described with reference to the drawings, wherein like reference numerals are used to refer to like elements throughout. In the following description, for purposes of explanation, numerous specific details are set forth in order to provide a thorough understanding of the subject innovation. It may be evident, however, that the disclosed subject matter may be practiced without these specific details. In other instances, well-known structures and devices are shown in block diagram form in order to facilitate describing the subject innovation.

Conventionally, wordlines and bitlines in a memory array can be formed in an orthogonal pattern, where memory cells can be at the point of crossing (e.g., intersection) of a respective wordline and a respective bit line. As memory devices become increasingly more dense to facilitate increased data storage capability and/or to decrease the package size of memory devices, the storage elements of adjacent memory cells can be situated increasingly closer to each other in the memory array. As adjacent storage elements of respective adjacent memory cells are positioned closer together, there can be cross-talk noise and/or complementary bit disturb (e.g., between storage elements in the same memory cell) between the storage elements during operations on such storage elements, which can negatively impact the performance of the storage elements and the memory device, as, for example, programming, reading, and/or erasing of storage elements can be negatively impacted due to the cross-talk noise and/or complementary bit disturb.

Devices and/or methods that facilitate reducing cross-talk noise and/or complementary bit disturb between adjacent storage elements in a memory device are presented. A memory device can include a memory array having wordlines formed in a zig-zag pattern such that each wordline can have segments that are parallel to the x-axis and other segments that are angled from a direction parallel to the x-axis based in part on a predetermined angle. In one embodiment, adjacent storage elements of the same memory cell can be positioned at respective ends of an angled segment of a wordline to facilitate increasing the distance between such storage elements, as compared to the distance between storage elements associated with an orthogonal memory array, where the increase in distance can be based in part on the predetermined angle. In another embodiment, adjacent storage elements of adjacent memory cells can be positioned at respective ends of an angled segment of a wordline to facilitate increasing the distance between such storage elements, as compared to the distance between storage elements associated with an orthogonal memory array, where the increase in distance can be based in part on the predetermined angle. The size of the memory array, and/or the memory device, can be the same or substantially the same size, as compared to an orthogonal memory array, as, while the length (e.g., associated with the y-axis) of the memory array can be increased due to the angling of the wordlines, the width (e.g. associated with the x-axis) of the memory array can be similarly decreased due to the angling of the wordlines.

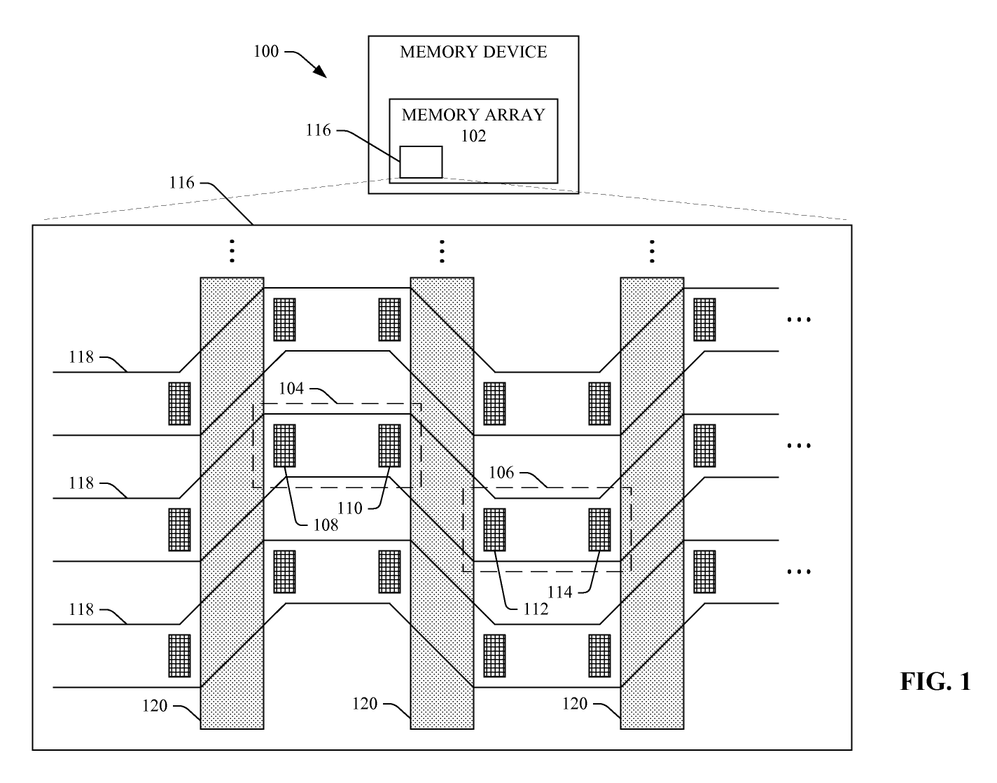

Turning to the figures, FIG. 1 illustrates a memory device 100 that can facilitate storage of data in accordance with an aspect of the disclosed subject matter. Memory device 100 can comprise a non-volatile memory (e.g., flash memory) and/or volatile memory (e.g., random access memory (RAM)). The memory device 100 can receive information, including data, commands, and/or other information, which the memory device 100 can process (e.g., store data, execute commands, etc.).

In one aspect, the memory device 100 can include a memory array 102 that can receive and store data. The memory array 102 can include a plurality of memory cells, including memory cell 104 and memory cell 106, wherein data can be stored. Each memory cell (e.g., 104, 106) can comprise two storage elements, as, for instance, memory cell 104 can comprise storage element 108 and storage element 110, and memory cell 106 can comprise storage element 112 and storage element 114. In accordance with an aspect, each storage element (e.g., 108) can store one or more bits of data. Data stored in a memory cell(s) in the memory array 102 can be read and such data can be provided as an output, or data can be erased from the memory cell(s). In one aspect, the memory array 102 can comprise a plurality of sectors, such as sector 116 (a portion of sector 116 is illustrated in FIG. 1), and respective subsets of memory cells can be contained in each sector in an array form.

In one aspect, the memory array 102 can comprise a plurality of wordlines 118 (hereinafter also referred to as “WLs 118”) and a plurality of bitlines 120 (hereinafter also referred to as “BLs 120”) that can facilitate forming the memory array 102, where respective WLs 118 and respective BLs 120 can intersect each other in the memory array 102. In another aspect, the memory cells (e.g., 104, 106) and respective storage elements (e.g., 108, 110, 112, 114) can each be situated in the memory array 102 at a respective point where a respective WL 118 and a respective BL 120 intersect.

Conventionally, wordlines and bitlines in a memory array can be formed in an orthogonal pattern, where memory cells can be at the point of crossing (e.g., intersection) of a respective wordline and a respective bit line. As memory devices become increasingly more dense to facilitate increased data storage capability and/or to decrease the package size of memory devices, the storage elements of adjacent memory cells can be situated increasingly closer to each other in the memory array. As adjacent storage elements of respective adjacent memory cells are positioned closer together, there can be cross-talk noise between the storage elements during operations on such storage elements, which can negatively impact the performance of the storage elements and the memory device, as, for example, programming, reading, and/or erasing of storage elements can be negatively impacted due to the cross-talk noise.

The subject innovation can facilitate reducing the amount of cross-talk noise between adjacent storage elements as the storage elements can be associated with a wordline (e.g., WL118) that can be formed in a zig-zag manner such that segments of the wordline can be angled from the conventional array pattern (e.g. orthogonal array), where the angling of the wordline can result in storage elements at each end of the angled segment of the wordline being spaced further apart from each other based in part on the amount of the angle, as compared to the amount of spacing the storage elements would have if positioned in a conventional array, such as an orthogonal array.

In one aspect, the BLs 120 can be straight or substantially straight on respective paths that can be parallel to the Y-axis, where a storage element (e.g., 110, 112) can be on each side of a respective BL 120 at or near the point where the BL 120 and a WL 118 cross each other. The WL 118 can have a segment that proceeds along a path parallel or substantially parallel to the X-axis, and at or near the point where the WL 118 crosses the BL 120, the WL 118 can be angled at a predetermined angle from the X-axis. For example, as illustrated in FIG. 1, the angled segment of the WL 118 can proceed at a predetermined positive angle (e.g., between 0 and 90 degrees) in an XY-direction from the angle (e.g., 0 degrees) associated with an x-axis. The segment of the WL 118 that is at the predetermined angle can proceed across the BL 120, and at or near the other side of the BL 120, the WL 118 can de-angle and return to a path along the X-axis (e.g. 0 degrees). The WL 118 can proceed along a path parallel to the X-axis until it is at or near the next BL 120, which can have a storage element on each side thereof, and at or near the next BL 120, the WL 118 can angle at another predetermined angle, where the angled segment of the WL 118 can proceed across the next BL 120 at the other predetermined angle. For instance, the segment of the WL 118 proceeding across the next BL 120 can be at a predetermined negative angle in an XY-direction from the angle (e.g., 0 degrees) associated with an x-axis, where the predetermined negative angle (e.g., between 0 and −90 degrees) can be a negative number of degrees (and/or another desired number of degrees), where the number is equal or substantially equal to the number of degrees of the predetermined positive angle (e.g., 45 degrees), but can be a negative number (e.g. −45 degrees). At or near the other side of the next BL 120, the WL 118 can again de-angle and that segment of the WL 118 can proceed along a path parallel or substantially parallel to the X-axis. The zig-zagging of the WL 118 can continue throughout the memory array 102. Each WL 118 can be structured in such zig-zag manner, such that each segment of a WL 118 can be parallel or substantially parallel to corresponding segments of the other WLs 118.

As a result of angling the WLs 118 so that the angled segment proceeds across a BL 120 at a predetermined angle, the adjacent storage elements (e.g., 110, 112) of respective adjacent memory cells (e.g., 104, 106) can be spaced further apart from each other based in part on the predetermined angle of the segment of the WL 118 associated therewith, as compared to the amount of space between adjacent storage elements in a conventional memory array (e.g., orthogonal array). In one aspect, the distance d between such adjacent storage elements (e.g., 110, 112) of memory device 100 can be d=x*F, where x can be the distance between the storage elements if the storage elements were in a conventional memory array (e.g. orthogonal array) wherein the wordline is straight along a path parallel to an X-axis, and F is a factor that can be a real number that is greater than 1 and can be based in part on the predetermined angle of the segment of the WL 118 associated with the two adjacent storage elements (e.g., 110, 112).

In one embodiment, the predetermined angle of the angled segment of the WL 118 associated with two adjacent storage elements (e.g., 110, 112) can be 45 degrees. As a result, the distance d can equal x*square root 2 based in part on the 45 degree angle of the segment of the WL 118. Thus, there can be approximately a 41% increase in the distance between the two adjacent storage elements (e.g. 110, 112) of the memory device 100 when the angled segment of the WL 118 is at an angle of 45 degrees, as compared to the distance between two adjacent storage elements in a conventional memory device. Angling segments of the WL 118 at angles different from 45 degrees but greater than 0 degrees and less than 90 degrees (or between 0 degrees and −90 degrees), can result in an increased distance between two adjacent storage elements in memory device 100, but the amount of increased distance between adjacent storage elements can vary based in part on the amount of the angle of the segment of the WL 118 associated with the two adjacent storage elements, with respect to the WL segments (e.g., WL segments parallel to x-axis) to the angled WL segment.

As a result of the increased distance between adjacent storage elements (e.g., 110, 112) of adjacent memory cells in the memory array 102, there can be a reduction in the cross-talk noise between such adjacent storage elements, which can improve overall performance of the memory device 100, including read, write, and/or erase performance, as compared to conventional memory devices. In accordance with an aspect, the overall area utilized by the memory array 102 can remain the same or substantially the same, where the WL 118 is shaped in a zig-zag manner. While the length (e.g., along the Y-axis) of the memory array 102 can be slightly increased due to the angling of the WLs 118, there can be a corresponding or substantially similar reduction in the width (e.g., along the X-axis) of the memory array 102 due to the angling of the WLs 118. The subject innovation, including the zig-zagging WLs 118, can be employed in virtually any memory device that utilizes a memory array, such as a memory device that conventionally would use an orthogonal array, of memory cells.

It is to be appreciated that, while memory device 100 depicts one memory array 102, the subject innovation is not so limited and there can be more than one memory array in memory device 100. For example, memory device 100 can comprise more than one memory array 102, or more than one memory array where each array can be associated with different types of memory (e.g. nonvolatile memory, volatile memory), where each such memory array can employ aspects of the subject innovation, include WLs 118 that can be formed in a zig-zag manner to facilitate increasing the distance between adjacent storage elements of respective adjacent memory cells.

It is to be further appreciated that, while memory device 100 is depicted with two storage elements per memory cell, the subject innovation is not so limited, as the memory cells of the memory device 100 can have less than two storage elements per memory cell, two storage elements per memory cell, or more than two storage elements per memory cell, in accordance with the disclosed subject matter.

In one aspect, the memory device 100 can comprise nonvolatile memory and/or volatile memory. The nonvolatile memory can include, but is not limited to, read-only memory (ROM), flash memory (e.g. single-bit flash memory, multi-bit flash memory), mask-programmed ROM, programmable ROM (PROM), Erasable PROM (EPROM), Ultra Violet (UV)-erase EPROM, one-time programmable ROM, electrically erasable PROM (EEPROM), phase change memory (PRAM), and/or nonvolatile RAM (e.g. ferroelectric RAM (FeRAM), FeRAM comprised of lead zironate titanate (PZT), magnetoresistive RAM (MRAM)). A nonvolatile memory can include various types of structures/layers, such as, for example, oxide-silicon rich nitride-polysilicon-silicon rich nitride-oxide (ORPRO)-type memory, silicon-oxide-nitride-oxide-silicon (SONOS)-type memory, floating gate-type memory, tantalum-aluminum-nitride-oxide-silicon (Ta—Al—NOS)-type memory, among others. A flash memory can be comprised of NAND memory and/or NOR memory, for example. Volatile memory can include, but is not limited to, RAM, static RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), Rambus direct RAM (RDRAM), direct Rambus dynamic RAM (DRDRAM), and Rambus dynamic RAM (RDRAM).

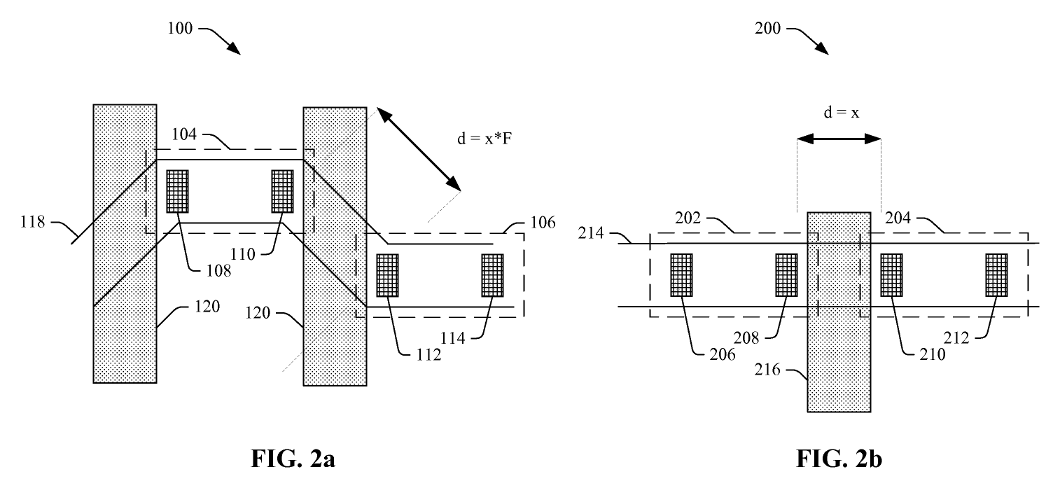

Referring to FIG. 2a, illustrated is a diagram of a portion of a memory array 102 associated with the memory device 100 in accordance with an aspect of the disclosed subject matter. The portion of the memory array 102 includes the memory cell 104, and its storage elements 108 and 110, and memory cell 106, and its storage elements 112 and 114. Memory array 102 also includes a WL 118 and BL 120 associated with memory cells 104 and 106.

In one aspect, the segment of the WL 118 between storage element 110 and storage element 112 can be at a predetermined angle (e.g., between 0 and 90 degrees, or between 0 and −90 degrees), as compared to the previous segment of the WL 118 which can proceed along a path parallel to the x-axis. The distance between the storage element 110 and storage element 112 can be based in part on the predetermined angle. The distance d can be equal to x*F, where x can be the space between the storage elements if the storage elements were in a conventional memory array (e.g., orthogonal array), such as depicted in FIG. 2b, wherein the WL is straight along the x-axis, and F is a factor that can be a real number that is greater than 1 and can be based in part on the predetermined angle of the segment of the WL 118 associated with the two adjacent storage elements (e.g., 110, 112).

Turning to FIG. 2b, depicted is a diagram of a portion of a memory array 200 of a memory device, where the array is orthogonal. The memory array 200 includes memory cell 202 and an adjacent memory cell 204, where memory cell 202 has storage elements 206 and 208 and memory cell 204 has storage elements 210 and 212. The memory cells 202 and 204 can be associated with WL 214 and BL 216, where adjacent storage elements 208 and 210 also can be associated with WL 214 and BL 216. The WL 214 is straight or substantially straight along the x-axis, and the BL 216 is straight or substantially straight along the y-axis. The distance between storage element 208 and adjacent storage element 210 is x.

Referring back to FIG. 2a, the distance between storage element 110 and adjacent storage element 112 can be d=x*F, where F can be a real number greater than 1. Thus, the amount of space between storage element 110 and storage element 112 can be greater than the amount of space between storage element 208 and storage element 210, as depicted in FIG. 2b. For example, where the predetermined angle is −45 degrees from the x-axis for the segment of the WL 118 associated with storage elements 110 and 112, the distance between storage element 110 and storage element 112 can be x*square root 2. As a result of the increased space between adjacent storage elements 110 and 112, the subject innovation can reduce the amount of cross-talk noise between storage element 110 and storage element 112, and can improve the performance of the memory device 100, as compared to conventional memory devices.

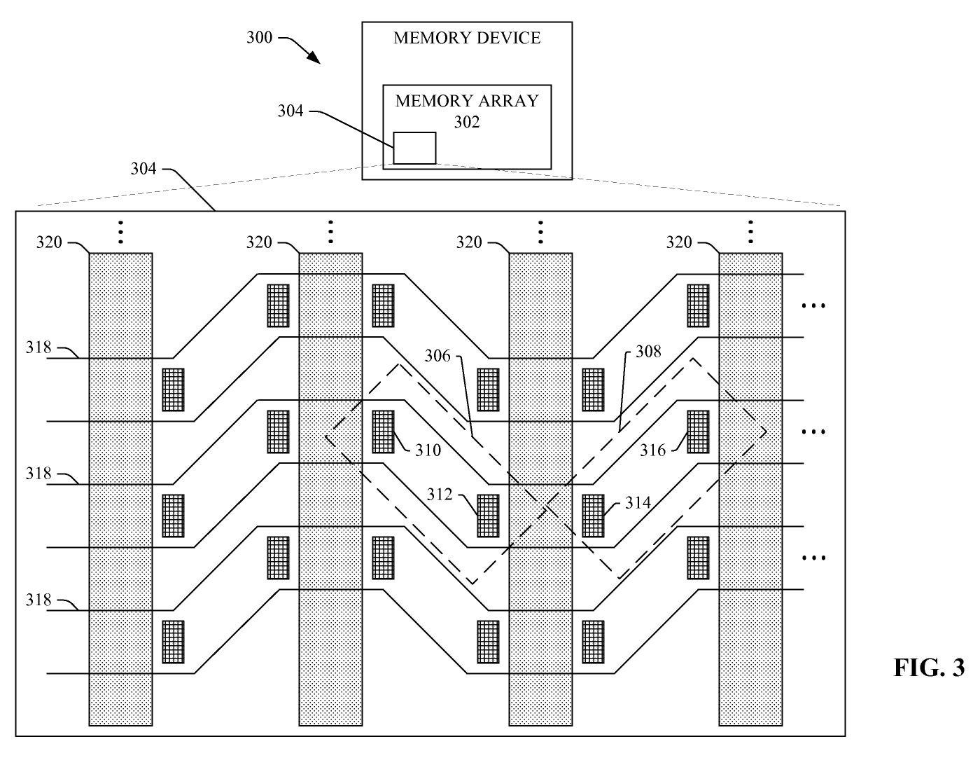

FIG. 3 illustrates a diagram of a memory device 300 that can facilitate reducing cross-talk noise and/or complementary bit disturb to facilitate storage of data in accordance with an embodiment of the disclosed subject matter. Memory device 300 can comprise a non-volatile memory (e.g. flash memory) and/or volatile memory (e.g., random access memory (RAM)). The memory device 300 can receive information, including data, commands, and/or other information, which the memory device 300 can process (e.g. store data, execute commands, etc.).

In one aspect, the memory device 300 can include a memory array 302 that can receive and store data. In another aspect, the memory array 302 can comprise a plurality of sectors, such as sector 304 (a portion of sector 304 is illustrated in FIG. 3), and respective subsets of memory cells, such as memory cell 306 and memory cell 308, can be contained in each sector in an array form. The memory array 302 can include a plurality of memory cells, including memory cell 306 and memory cell 308, wherein data can be stored. Each memory cell (e.g., 306, 308) can comprise two storage elements, as, for instance, memory cell 306 can comprise storage element 310 and storage element 312, and memory cell 308 can comprise storage element 314 and storage element 316. In accordance with an aspect, each storage element (e.g., 310, 312, 314, 316) can store one or more bits of data. Data stored in a memory cell(s) in the memory array 302 can be read and such data can be provided as an output, or data can be erased from the memory cell(s).

In one aspect, the memory array 302 can comprise a plurality of wordlines 318 (hereinafter also referred to as “WLs 318”) and a plurality of bitlines 320 (hereinafter also referred to as “BLs 320”) that can facilitate forming the memory array 302, where respective WLs 318 and respective BLs 320 can intersect each other in the memory array 302. In another aspect, the memory cells (e.g., 306, 308) and respective storage elements (e.g., 310, 312, 314, 316) can each be situated in the memory array 302 at a respective point where a respective WL 318 and a respective BL 320 intersect.

Conventionally, wordlines and bitlines in a memory array can be formed in an orthogonal pattern, where memory cells can be at the point of intersection of a respective wordline and a respective bit line. As memory devices become increasingly more dense to facilitate increased data storage capability and/or to decrease the package size of memory devices, the storage elements of memory cells can be situated increasingly closer to each other in the memory array. As storage elements of a memory cell are positioned closer together, there can be cross-talk noise and/or complementary bit disturb between the storage elements during operations on such storage elements, which can negatively impact the performance of the storage elements and the memory device, as, for example, programming, reading, and/or erasing of storage elements can be negatively impacted due to the cross-talk noise and/or complementary bit disturb.

The subject innovation can facilitate reducing the amount of cross-talk noise and/or complementary bit disturb between storage elements in a memory cell as the storage elements can be associated with a wordline that can be formed in a zig-zag manner such that segments of the wordline can be angled from the conventional array pattern (e.g., orthogonal array), where the angling of the wordline can result in storage elements of the memory cell being at each end of the angled segment of the wordline such that the storage elements can be spaced further apart from each other based in part on the amount of the angle of the wordline, as compared to the amount of spacing the storage elements would have if positioned in a conventional array, such as an orthogonal array.

In one aspect, the BLs 320 can be straight or substantially straight paths parallel or substantially parallel to the y-axis, where storage elements (e.g., 310, 312, 314, 316) can be associated with respective adjacent BLs 320 and associated with a WL 318 that can intersect each BL 320. In accordance with an aspect, a WL 318 can have a segment that can proceed along a path parallel to the x-axis, and at or near a point where the WL 318 crosses (e.g., intersects) a BL 320 and/or meets a storage element (e.g., 310) associated with one side a memory cell (e.g., 306), the WL 318 can be angled at a predetermined angle from path of the other segment that is parallel or substantially parallel to the x-axis. For example, as illustrated in FIG. 3, the angled segment of the WL 318 associated with memory cell 306 can proceed at a predetermined negative angle (e.g., between 0 and −90 degrees) in an xy-direction at or near storage element 310 and/or BL 320 associated with storage element 310. The segment of the WL 318 that is at the predetermined angle can proceed across the memory cell 306, and at or near the other side of the memory cell 306, such as at or near storage element 312 and/or the next BL 320 associated therewith, the WL 318 can de-angle and return to a path that can be parallel or substantially parallel to the x-axis.

The WL 318 can proceed along a path parallel or substantially parallel to the x-axis until it is at or near the next memory cell (e.g., 308), which can have a storage element (e.g., 314, 316) on each side thereof, and at or near the next memory cell (e.g., 308) and/or the storage element (e.g., 314) on the one side of the next memory cell, the WL 318 can angle at another predetermined angle, where the angled segment of the WL 318 can proceed across the next memory cell (e.g., 308) at the other predetermined angle that can deviate from the path of the previous segment, which is parallel or substantially parallel to the x-axis. For instance, such segment of the WL 318 proceeding across the next memory cell (e.g. 308) can be at a predetermined positive angle in the xy-direction, where the predetermined positive angle (e.g., between 0 and 90 degrees) can be equal or substantially equal in the number of degrees to the predetermined negative angle, but the angle can be a positive number of degrees. At or near the other side of the next memory cell (e.g., 308) and/or at or near storage element (e.g., 314) associated therewith and/or the BL 320 associated with that storage element (e.g., 314), the WL 318 can again de-angle and that segment of the WL 318 can proceed along a path that can be parallel or substantially parallel to the x-axis. The zig-zagging of the WL 318 can continue throughout the memory array 302. Each WL 318 can be structured in such zig-zag manner, such that each segment of a WL 318 can be parallel or substantially parallel to corresponding segments of the other WLs 318.

As a result of angling the WLs 318 so that the angled segment proceeds across a memory cell (e.g., 306) at a predetermined angle, the storage elements (e.g., 310, 312) of the memory cell (e.g. 308) can be spaced further apart from each other based in part on the predetermined angle of the segment of the WL 318 associated therewith, as compared to the amount of space between the storage elements of a memory cell in a conventional memory array (e.g. orthogonal array). In one aspect, the distance d between such storage elements (e.g., 310, 312) of a memory cell (e.g., 306) in memory device 300 can be d=y*F, wherey can be the distance between the storage elements if the storage elements were in a conventional memory array (e.g., orthogonal array), wherein the WL is straight along an x-axis, and F is a factor that can be a real number that is greater than 1 and can be based in part on the predetermined angle of the segment of the WL 318 associated with the two storage elements (e.g., 310, 312) of a memory cell (e.g., 306).

In one embodiment, the predetermined angle of the angled segment of the WL 318 associated with two storage elements (e.g., 310, 312) of a memory cell (e.g., 306) can be 45 degrees. As a result, the distance d can equal y*square root 2 based in part on the 45 degree angle of the segment of the WL 318. Thus, there can be approximately a 41% increase in the distance between the two storage elements (e.g., 310, 312) on each side of a memory cell (e.g., 306) of the memory device 300 when the angled segment of the WL 318 is at an angle of 45 degrees, as compared to the distance between two storage elements of a memory cell in a conventional memory device. Angling segments of the WL 318 at angles different from 45 degrees but greater than 0 degrees and less than 90 degrees (or between 0 and −90 degrees), can result in an increased distance between two storage elements of a memory cell in memory device 300, but the amount of increased distance between adjacent storage elements can vary based in part on the amount of the angle of the segment of the WL 318 associated with the two storage elements of a memory cell.

As a result of the increased distance between the storage elements (e.g., 310, 312) of a memory cell (e.g., 306) in the memory array 302, there can be a reduction in complementary bit disturb and/or cross-talk noise between such storage elements, which can improve overall performance of the memory device 300, including read, write, and/or erase performance, as compared to conventional memory devices. In accordance with an aspect, the overall area utilized by the memory array 302 can remain the same or substantially the same, where the WL 318 is shaped in a zig-zag manner. While the length (e.g., along the y-axis) of the memory array 302 can be slightly increased due to the angling of the WLs 318, there can be a corresponding or substantially similar reduction in the width (e.g., along the x-axis) of the memory array 302 due to the angling of the WLs 318. The subject innovation, including the zig-zagging WLs 318, can be employed in virtually any memory device that utilizes a memory array, such as a memory device that conventionally would use an orthogonal array, of memory cells.

It is to be appreciated that, while memory device 300 depicts one memory array 302, the subject innovation is not so limited and there can be more than one memory array in memory device 300. For example, memory device 300 can comprise more than one memory array 302, or more than one memory array where each array can be associated with different types of memory (e.g. nonvolatile memory, volatile memory), where each such memory array can employ aspects of the subject innovation, including WLs that are formed in a zig-zag manner to facilitate increasing the distance between adjacent storage elements of respective adjacent memory cells. It is to be further appreciated that, while memory device 300 is depicted with two storage elements per memory cell, the subject innovation is not so limited, as the memory cells of the memory device 300 can include two or more storage elements per memory cell, in accordance with the disclosed subject matter.

In one aspect, the memory device 300 can comprise nonvolatile memory and/or volatile memory. The nonvolatile memory can include, but is not limited to, read-only memory (ROM), flash memory (e.g. single-bit flash memory, multi-bit flash memory), mask-programmed ROM, programmable ROM (PROM), Erasable PROM (EPROM), Ultra Violet (UV)-erase EPROM, one-time programmable ROM, electrically erasable PROM (EEPROM), phase change memory (PRAM), and/or nonvolatile RAM (e.g. ferroelectric RAM (FeRAM), FeRAM comprised of lead zironate titanate (PZT), magnetoresistive RAM (MRAM)). A nonvolatile memory can include various types of structures/layers, such as, for example, oxide-silicon rich nitride-polysilicon-silicon rich nitride-oxide (ORPRO)-type memory, silicon-oxide-nitride-oxide-silicon (SONOS)-type memory, floating gate-type memory, tantalum-aluminum-nitride-oxide-silicon (Ta—Al—NOS)-type memory, among others. A flash memory can be comprised of NAND memory and/or NOR memory, for example. Volatile memory can include, but is not limited to, RAM, static RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), Rambus direct RAM (RDRAM), direct Rambus dynamic RAM (DRDRAM), and Rambus dynamic RAM (RDRAM).

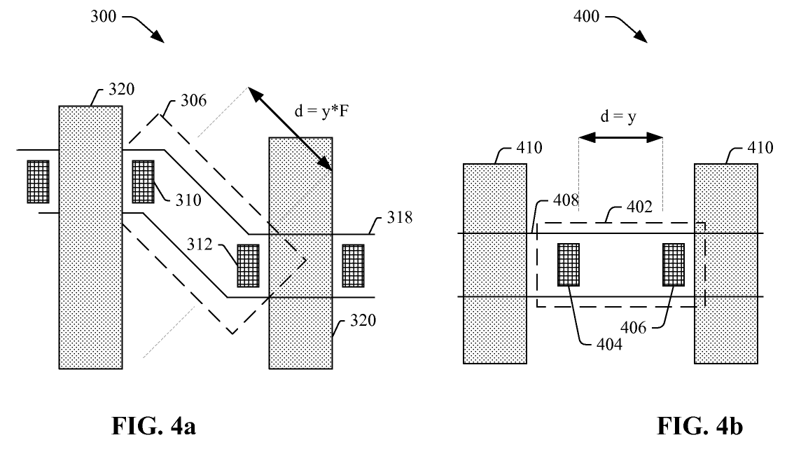

Referring to FIG. 4a, illustrated is a diagram of a portion of a memory array 302 associated with the memory device 300 in accordance with an aspect of the disclosed subject matter. The portion of the memory array 302 includes the memory cell 306, and its storage elements 310 and 312. Memory array 302 also includes a WL 318 and BLs 320 associated with the memory cell 306.

In one aspect, the segment of the WL 318 between storage element 310 and storage element 312 of memory cell 306 can be at a predetermined angle, as compared to the previous segment of the WL 318, which can proceed along path that can be parallel or substantially parallel to the x-axis. The distance between the storage element 310 and storage element 312 can be based in part on the predetermined angle. The distance d can be equal to y*F, where y can be the distance between the storage element 310 and storage element 312 if the storage elements were in a conventional memory array (e.g. orthogonal array), such as depicted in FIG. 4b, wherein the WL is straight along a path parallel to the x-axis, and F can be a factor that can be a real number that is greater than 1 and can be based in part on the predetermined angle (e.g., between 0 and 90 degrees, or between 0 and −90 degrees) of the segment of the WL 318 associated with the two storage elements 310, 312 of memory cell 306.

Turning to FIG. 4b, depicted is a diagram of a portion of a memory array 400 of a memory device, where the array is orthogonal. The memory array 400 includes memory cell 402, where memory cell 402 has storage elements 404 and 406. The memory cell 402 can be associated with WL 408 and BLs 410, where storage elements 404 and 406 also can be associated with WL 408 and respective BLs 410. The WL 408 is straight or substantially straight along path parallel to the x-axis, and the BLs 410 are straight or substantially straight along a path parallel to the y-axis. The distance between storage element 404 and storage element 406 is y.

Referring back to FIG. 4a, the distance between storage element 310 and storage element 312 in memory cell 306 can be d=y*F, where F can be a real number greater than 1. Thus, the amount of space between storage element 310 and storage element 312 can be greater than the amount of space between storage element 404 and storage element 406 of memory cell 402, as depicted in FIG. 4b. For example, where the predetermined angle is −45 degrees from the x-axis for the segment of the WL 318 associated with storage elements 310 and 312, the distance between storage element 310 and storage element 312 of memory cell 306 can be y*square root 2. As a result of the increased space between the storage elements 310 and 312 of memory cell 306, the subject innovation can reduce the amount of complementary bit disturb and/or cross-talk noise between storage element 310 and storage element 312, and can improve the performance of the memory device 300, as compared to conventional memory devices.

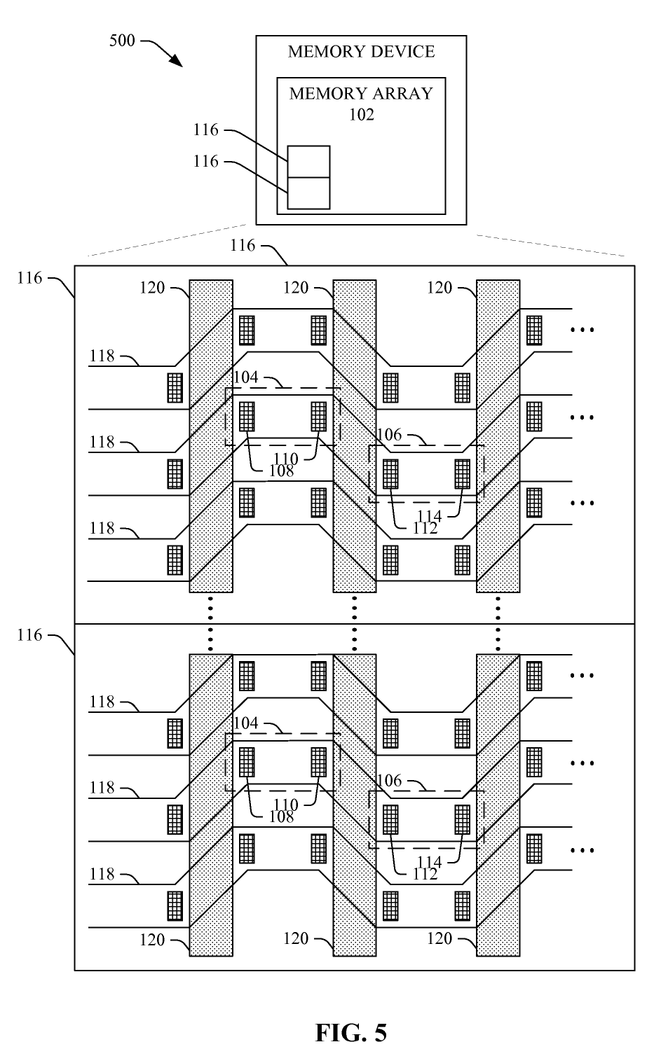

Referring to FIG. 5, illustrated is another diagram of a memory device 100 in accordance with an aspect of the disclosed subject matter. Memory device 100 can comprise a memory array 102 that can include a plurality of sectors 116, where two sectors 116 are shown in FIG. 5 for illustrative purposes. The memory array 102 can include a plurality of memory cells, such as memory cell 104 and memory cell 106, where each sector 116 can comprise a subset of memory cells. Each memory cell (e.g., 104, 106) can contain two storage elements, such as storage elements 108 and 110 that can be contained in memory cell 104, and storage elements 112 and 114 that can be contained in memory cell 106. Memory array 102 can comprise a plurality of WLs 118 and BLs 120 that can be formed in an intersecting array, where the memory cells (e.g., 104, 106) can be located at points of intersection of respective WLs 118 and respective BLs 120. The memory device 100, memory array 102, memory cells (e.g., 104, 106), storage elements (e.g., 108, 110, 112, 114), sectors (e.g. 116), WLs 118, and BLs 120, each can be the same or similar to respective components, and/or can comprise the same or similar respective functionality as respective components, as more fully described herein, for example, with regard to memory device 100.

In one aspect, the WLs 118 of each sector 116 can be structured in a zig-zag manner to facilitate increasing the distance between the storage element (e.g., 110) of a memory cell (e.g., 104) and an adjacent storage element (e.g., 112) of an adjacent memory cell (e.g., 106) along the same WL 118 to facilitate reducing the amount of cross-talk noise between such storage elements, which can thereby improve the overall performance of the memory device 100. The zig-zag structure of the WLs 118 can be the same or similar across each sector 116 such that the respective segments of the WLs 118 (e.g., whether on a path parallel to x-axis path or angled) of each sector 116 can be parallel or substantially parallel to respective segments of the WLs 118 of an adjacent sector above or below the sector 116. As a result, the memory array 102 can be structured in an efficient manner to facilitate minimizing the area utilized by the memory array 102.

It is to be appreciated that, while multiple sectors are depicted herein with respect to memory device 100, the subject innovation is not so limited, as the subject innovation contemplates that another memory device (e.g. 300), where the angling of the WLs (e.g., 318) can be across the memory device to facilitate increasing the distance between storage elements (e.g., 310, 312) of a memory cell (e.g., 306) to facilitate reducing complementary bit disturb and/or cross-talk noise between storage elements, can also comprise multiple sectors that can utilize WLs zig-zagging such that respective segments of the WLs of each sector and across each sector can be parallel and/or substantially parallel to each other.

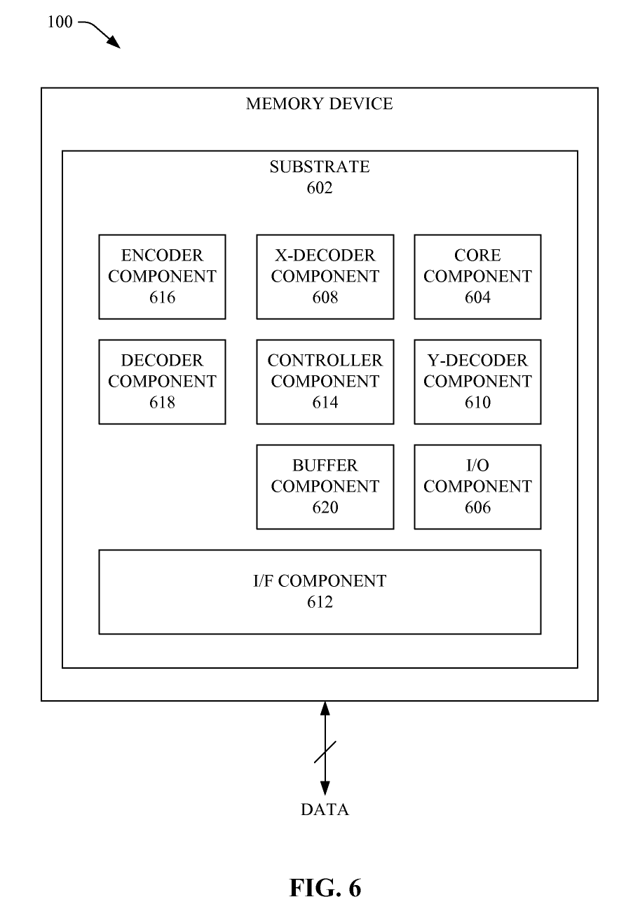

FIG. 6 depicts a block diagram of a memory device 100 that can facilitate access of data in a memory in accordance with one embodiment of the disclosed subject matter. Memory device 100 can comprise non-volatile memory (e.g., single-bit flash memory, multi-bit flash memory) and/or volatile memory (e.g. SRAM). For example, the memory device 100 can comprise NOR flash memory and/or NAND flash memory. The memory device 100 can include a memory array (e.g., memory array 102, as illustrated in FIG. 1 and described herein) that can be comprised of a plurality of memory cells (e.g., such as memory cells 104 and 106, as illustrated in FIG. 1 and described herein), which can be memory locations, wherein, for each memory cell, one or more bits of data can be stored, and from which stored data can be read. Each memory cell can include storage elements (e.g., 108, 110, 112, 114, as depicted in FIG. 1 and described herein) wherein data can be stored. The memory array 102 can comprise a plurality of sectors (e.g. 116, as depicted in FIG. 1 and described herein), where each sector can include a subset of the memory cells. Each memory cell can be associated with respective WL(s) 118 and BL(s) 120. It is to be appreciated that the memory device 100, memory array 102, memory cells (e.g. 104, 106), storage elements (e.g., 108, 110, 112, 114), sectors 116, WLs 118, and BLs 120, each can be the same or similar as respective components, and/or can contain the same or similar functionality as respective components, as more fully described herein, for example, with regard to memory device 100.

In one aspect, the memory device 100, including the memory array 102, memory cells (e.g. 104, 106), storage elements (e.g., 108, 110, 112, 114), sectors (e.g., 116), WLs 118, and BLs 120, such as described herein, for example, with regard to memory device 100, can be formed and/or contained on a substrate 602 (e.g., semiconductor substrate). In another aspect, one or more core components 604 (e.g., high-density core regions) and one or more lower-density peripheral regions can be formed on the substrate component 602. The core component(s) 604 typically can include one or more M by N arrays (e.g., memory array 102) of individually addressable, substantially identical multi-bit memory cells (e.g., 104, 106). The lower-density peripheral regions can typically include an input/output component 606 (e.g., input/output (I/O) circuitry) and programming circuitry for selectively addressing the individual memory cells. The programming circuitry can be represented in part by and can include one or more x-decoder components 608 and one or more y-decoder components 610 that can cooperate with the I/O component 606 for selectively connecting a source (not shown), gate (not shown), and/or drain (not shown) of selected addressed memory cells to predetermined voltages or impedances to effect designated operations (e.g. programming, reading, verifying, erasing) on the respective memory cells, and deriving necessary voltages to effect such operations. For example, an x-decoder component 608 and a y-decoder component 610 can each receive address bus information, which can be provided as part of a command, and such information can be utilized to facilitate determining the desired memory cell(s) in the memory device 100.

The memory device 100 can receive information (e.g., data, commands, etc.) via an interface component 612 (also referred to herein as “I/F 612”), which can also be formed on substrate 602. I/F 612 can include and/or provide various adapters, connectors, channels, communication paths, etc. to integrate the memory device 100 into virtually any operating and/or database system(s) and/or with one another system(s). In addition, I/F 612 can provide various adapters, connectors, channels, communication paths, etc., that can provide for interaction and/or communication with a processor component (not shown), and/or any other component, data, and the like, associated with the memory device 100.

The memory device 100 can also contain a memory controller component 614 that can facilitate control of the flow of data to and from the memory device 100. In an aspect, the memory controller 614 can facilitate execution of operations (e.g., read, write, verify, erase) associated with memory locations (e.g., memory cells) in the memory array 102. In another aspect, the memory controller 614 can facilitate verifying and/or maintaining the desired charge level(s) associated with data stored in the memory locations in the memory array 102. The memory device 100 also can include an encoder component 616 that can facilitate encoding data being programmed to the memory device 100, where the encoder component 616 also can be formed on the substrate 602. For example, the encoder component 616 can facilitate converting a digital signal to an analog signal (e.g., current level) to facilitate programming data in the memory locations in the memory device 100.

The memory device 100 can further include a decoder component 618 that can facilitate decoding data being read from the memory device 100. The decoder component 618 can receive an analog signal associated with data, where the analog signal can be stored in the memory location in the memory array 102, and can facilitate converting the analog signal to a digital signal, so that such digital signal representing the read data can be provided to another component (e.g., processor component (not shown)) for further processing. The memory device 100 can comprise a buffer component 620 (e.g., SRAM) that can be formed on the substrate 602 and can facilitate data transfers to or from the core component(s) 604.

The aforementioned devices have been described with respect to interaction between several device components. It should be appreciated that such devices and components can include those components or sub-components specified therein, some of the specified components or sub-components, and/or additional components. Sub-components could also be implemented as components communicatively coupled to other components rather than included within parent components. Further yet, one or more components and/or sub-components may be combined into a single component providing aggregate functionality. The components can also interact with one or more other components not specifically described herein for the sake of brevity, but known by those of skill in the art.

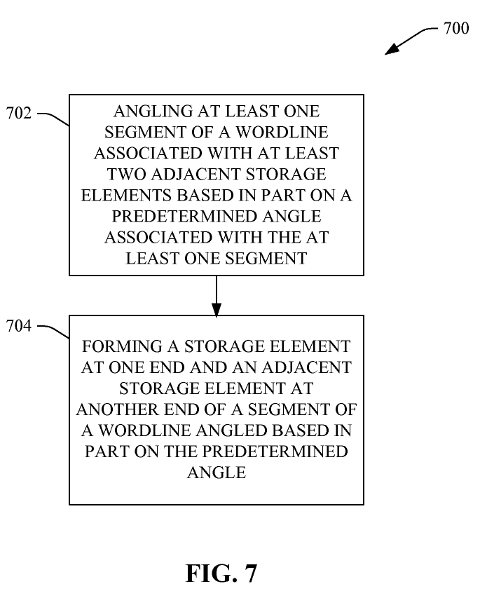

FIGS. 7-9 illustrate methodologies and/or flow diagrams in accordance with the disclosed subject matter. For simplicity of explanation, the methodologies are depicted and described as a series of acts. It is to be understood and appreciated that the subject innovation is not limited by the acts illustrated and/or by the order of acts, for example acts can occur in various orders and/or concurrently, and with other acts not presented and described herein. Furthermore, not all illustrated acts may be required to implement the methodologies in accordance with the disclosed subject matter. In addition, those skilled in the art will understand and appreciate that the methodologies could alternatively be represented as a series of interrelated states via a state diagram or events. Additionally, it should be further appreciated that the methodologies disclosed hereinafter and throughout this specification are capable of being stored on an article of manufacture to facilitate transporting and transferring such methodologies to computers. The term article of manufacture, as used herein, is intended to encompass a computer program accessible from any computer-readable device, carrier, or media.

Referring to FIG. 7, a methodology 700 that can facilitate data storage associated with a memory device in accordance with an aspect of the disclosed subject matter is illustrated. At 702, angling at least one segment of a wordline associated with at least two adjacent storage elements based in part on a predetermined angle associated with the at least one segment to facilitate increasing the distance between the at least two adjacent storage elements. At 704, forming the at least two adjacent storage elements, wherein a storage element is formed at one end and an adjacent storage element is formed at another end of a segment of a wordline angled based in part on the predetermined angle. In accordance with one aspect, the WLs (e.g., 118, 318) of a memory array (e.g., 102, 302) can be structured in a zig-zag manner such that the distance between adjacent storage elements (e.g., 110, 112, 310, 312) can be increased, as compared to adjacent storage elements in a conventional memory array (e.g., orthogonal memory array), to facilitate reducing cross-talk noise and/or complementary bit disturb between the adjacent storage elements associated with an angled segment of the WL.

In one embodiment, a WL (e.g., 118) can be on a path parallel or substantially parallel to the x-axis and, at or near a storage element (e.g., 110) associated with a first memory cell (e.g., 104) that can be associated with the WL, the WL can angle based in part on a predetermined angle (e.g., between 0 and 90 degrees, or between 0 and −90 degrees), so that the path of the WL proceeds in an xy-direction. At or near the point where the WL meets a storage element (e.g., 112) that can be adjacent to the first storage element (e.g., 110), the WL can de-angle (e.g., to 0 degrees) such that the WL can proceed on a path parallel or substantially parallel to the x-axis. In one aspect, the WL can continue along such path and when it is at or near the next storage element, the WL can angle at a different angle (e.g., opposite to the predetermined angle, such as 45 degrees if the predetermined angle is 45 degrees) from the first angle so that the WL is again proceeding on a path in an xy-direction, but at an angle that can be, for example, opposite (e.g., negative) or substantially opposite to the angle of the first-angled segment of the WL. The WL can proceed in such a zig-zag pattern until it reaches the end of the memory array. Also, other WLs in the memory array can be similarly formed in a zig-zag manner such that respective segments of the WLs of the memory array can be parallel and/or substantially parallel to each other.

In accordance with another embodiment, a WL (e.g., 318) can be on a path that can be parallel or substantially parallel to the x-axis and, at or near a storage element (e.g., 310) associated with a memory cell (e.g., 306) that can be associated with the WL, the WL can angle based in part on a predetermined angle (e.g., −45 degrees), so that the path of the WL can proceeds in the xy-direction. At or near the point where the WL meets another storage element (e.g., 312) of the memory cell, the WL can de-angle such that the WL can proceed on a path parallel or substantially parallel to the x-axis. In one aspect, the WL can continue along such path and when it is at or near the next storage element (e.g., 314) of the next memory cell (e.g., 308), the WL can angle in a different (e.g. opposite) angle (e.g., 45 degrees) from the first angle so that the WL is again proceeding on a path in an xy-direction, but at an angle that can be, for example, opposite (e.g., positive) or substantially opposite to the angle of the first-angled segment of the WL. At or near the point where the angled segment of the WL reaches the other storage element (e.g., 316) of that memory cell, the WL can be de-angled so that it can proceed along a path parallel or substantially parallel to the x-axis. The WL can proceed in such a zig-zag pattern until it reaches the end of the memory array. In another aspect, other WLs in the memory array can be similarly formed in a zig-zag manner such that respective segments of the WLs of the memory array can be parallel and/or substantially parallel to each other.

The subject innovation can facilitate increasing the distance between adjacent storage elements, such as storage elements in the same memory cell and/or storage elements in adjacent memory cells, along the same WL to facilitate reducing cross-talk noise and/or complementary bit disturb between adjacent storage elements in the memory array of the memory device, which can increase the performance of the memory device, as compared to conventional memory devices, such as memory devices that have an orthogonal memory array. At this point, methodology 700 can end.

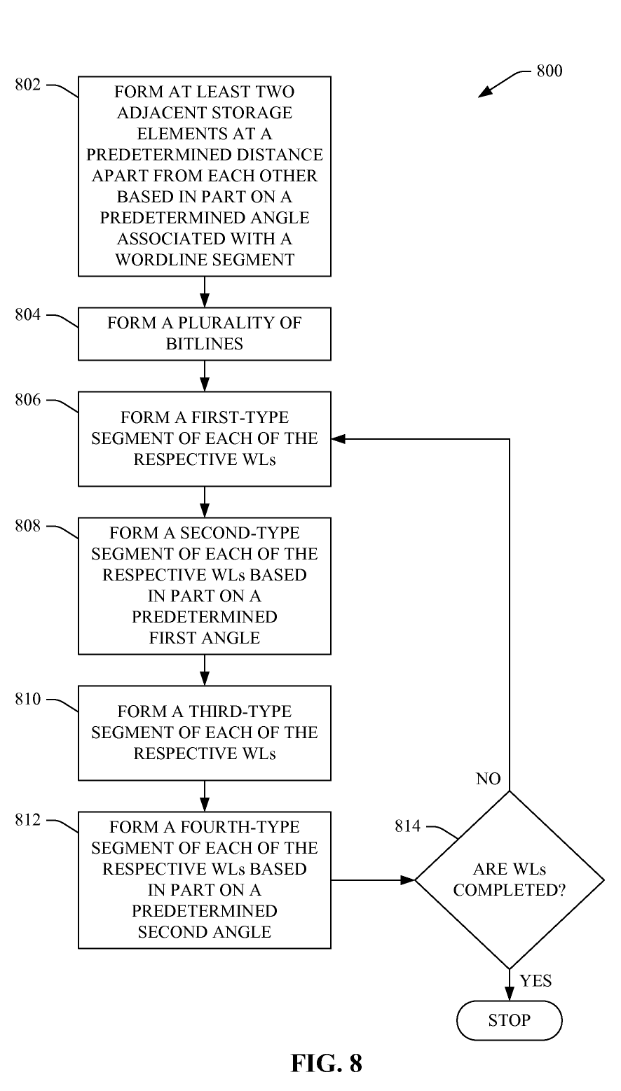

Turning to FIG. 8, depicted is a methodology 800 that can facilitate reducing cross-talk noise associated with memory cells in a memory in accordance with an embodiment of the disclosed subject matter. At 802, two or more storage elements (e.g., storage element 110, storage element 112) can be formed at a predetermined distance apart from each other based in part on a segment of a wordline of a plurality of wordlines (e.g., WL 118) that can be formed at a predetermined angle from an x-axis. In one aspect, there can be a plurality of memory cells that can each have one or more storage elements contained therein. The memory cells and respective storage elements can be formed at or near respective locations in the memory array where respective BLs and WLs cross in the memory array, and each memory cell and/or storage element can be associated with a corresponding BL and corresponding WL.

At 804, a plurality of bitlines (e.g., BL 120) can be formed that are each parallel or substantially parallel to a y-axis. In one aspect, each BL can be associated with a respective subset of memory cells and storage elements associated therewith in the memory array of the memory device, where the memory cells and associated storage elements can be formed at or near the sides of the respective BLs where the respective BLs cross with respective WLs in the memory array.

At 806, a first-type segment of each of the respective WLs of a plurality of WLs can be formed, where each first-type segment can be formed parallel or substantially parallel to an x-axis. In one aspect, each respective first-type segment can extend to at or near the location of a BL (e.g., first BL) in the memory array.

At 808, a second-type segment of each of the respective WLs can be formed, where each second-type segment can be angled at a predetermined first angle (e.g., positive angle between 0 and 90 degrees) from the x-axis based in part on the predetermined first angle. In one aspect, the second-type segment of respective WLs can be connected with respective first-type segments and can extend at the predetermined first angle from the x-axis as the respective second-type segments cross the BL (e.g., first BL) in the memory array.

At 810, a third-type segment of each of the respective WLs can be formed, where each third-type segment can be de-angled to proceed on a path parallel or substantially parallel to the x-axis. In one aspect, each of the respective third-type segments can be connected with respective second-type segments of the WLs. At or near a location on the other side of the BL (e.g., first BL) that the respective WLs crossed, each third-type segment of respective WLs can be de-angled such that the third-type segment can proceed along a path that can be parallel or substantially parallel to the x-axis.

At 812, a fourth-type segment of each of the respective WLs can be formed, where each fourth-type segment can be angled at a predetermined second angle (e.g., negative angle between 0 and −90 degrees) from the x-axis based in part on the predetermined second angle. In one aspect, each respective fourth-type segment of respective WLs can be connected with respective third-type segments and can extend at the predetermined second angle from the x-axis as the respective fourth-type segments cross the next BL (e.g., second BL) in the memory array.

At 814, a determination can be made as to whether the plurality of WLs are completed (e.g., are extended across the memory array). If it is determined that the plurality of WLs are not completed, methodology 800 can return to reference numeral 806, where additional WL segments (e.g., first-type segment(s), second-type segment(s), third-type segment(s), fourth-type segment(s)) can be formed, and methodology 800 can proceed until the plurality of WLs have been completely formed in the memory array. If, at 814, it is determined that the plurality of WLs are completely formed (e.g., extended across the memory array), methodology 800 can end.

In one aspect, methodology 800 can facilitate increasing the distance between adjacent storage elements respectively associated with adjacent memory cells along a WL, where the increased distance between such storage elements can facilitate reducing cross-talk noise between such storage elements, as compared to conventional memory arrays, such an orthogonal memory arrays, for example. For instance, conventionally, in an orthogonal memory array, two adjacent storage elements of respective adjacent memory cells can be a distance d apart, where d can equal x.

The subject innovation, by employing methodology 800, for example, can facilitate increasing the distance between two adjacent storage elements (e.g., storage element 110 and storage element 112) of two adjacent memory cells (e.g., memory cell 104 and memory cell 106), by angling certain segments of the WL associated with such storage elements so that one of the adjacent storage elements can be at one end of the angled segment of the WL and the other adjacent storage element can be at the other end of the angled segment of the WL, where the angling of the WL segment can facilitate increasing the distance between such adjacent storage elements based in part on the predetermined angle of the WL with respect to the WL segments to which the angled segment is connected. In one aspect, the predetermined angle of a particular angled WL segment can be between 0 and 90 degrees from the x-axis, or between 0 and −90 degrees. As a result of the angling of the WL segment, the distance d between the adjacent storage elements can be equal to x*F, where x can be the distance between two adjacent storage elements of a conventional memory array (e.g., with an orthogonal array) and F can be a real number that is greater than 1 and can be based in part on the angle between the angled WL segment and the WL segment to which the angled WL segment is connected and from which it is angling on a path in a different direction.

For example, in one embodiment, a WL segment between two adjacent storage elements can be angled at −45 degrees from the x-axis, and/or from a connected WL segment that is on a path parallel or substantially parallel to the x-axis. As a result of angling the WL segment, the distance d between the two adjacent storage elements can be x*square root 2, where x can be the distance between two adjacent storage elements of a conventional memory array (e.g., with an orthogonal array).

It is to be appreciated that a memory array can comprise a plurality of sectors that each can contain a subset of the plurality of WLs. The WL spacing between a bottom WL of a sector and a top WL of another sector below the sector in the memory array can be the same distance or substantially the same distance as the distance between the respective WLs in a sector (e.g., the bottom WL in the sector and a WL adjacent to the WL in the sector).

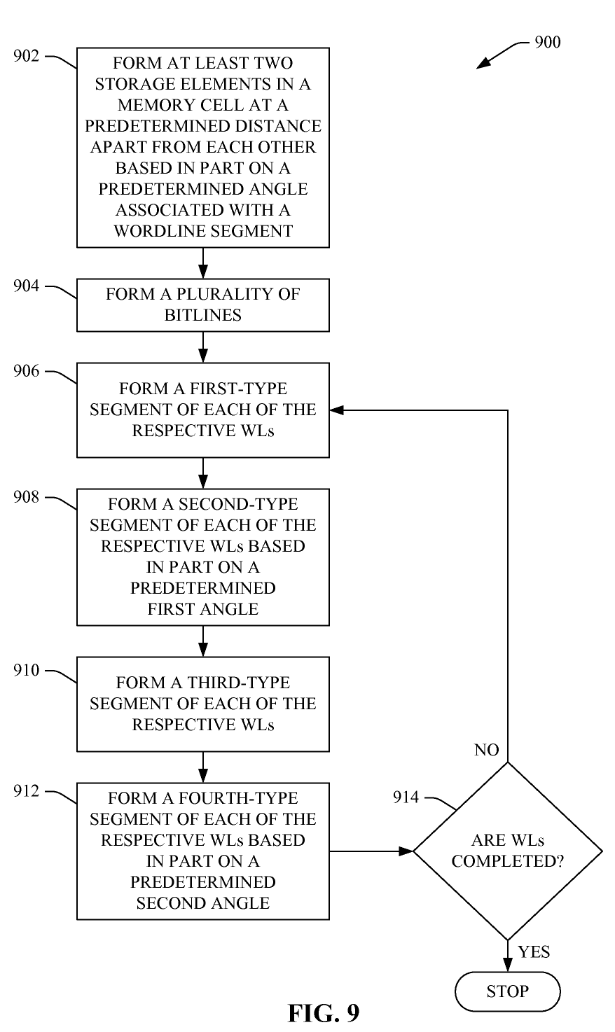

FIG. 9 depicts a methodology 900 that can facilitate reducing complementary bit disturb and/or cross-talk noise associated with storage elements in memory cells associated with a memory device in accordance with an embodiment of the disclosed subject matter. At 902, two or more storage elements can be formed at a predetermined distance apart from each other based in part on a segment of a wordline of a plurality of wordlines (e.g., WL 318) that can be formed at a predetermined angle from an x-axis. In one aspect, there can be a plurality of memory cells that can each have at least two storage elements contained therein. The memory cells and respective storage elements can be formed at or near respective locations in the memory array where respective BLs and WLs cross in the memory array, and each memory cell and/or storage element can be associated with a corresponding BL and corresponding WL.

At 904, a plurality of bitlines (e.g., BL 320) can be formed that are each parallel or substantially parallel to a y-axis. In one aspect, each BL can be associated with a respective subset of memory cells and storage elements associated therewith in the memory array of the memory device, where the memory cells and associated storage elements can be formed at or near the sides of respective BLs where the respective BLs cross with respective WLs in the memory array.

At 906, a first-type segment of each of the respective WLs of a plurality of WLs can be formed, where each first segment can be formed parallel or substantially parallel to an x-axis. In one aspect, each respective first-type segment can extend across a BL (e.g., first BL) in the memory array.

At 908, a second-type segment of each of the respective WLs can be formed, where each second-type segment can be angled at a predetermined first angle (e.g., positive angle between 0 and 90 degrees) from the x-axis based in part on the predetermined first angle. In one aspect, the second-type segment of respective WLs can be connected with respective first-type segments and can extend at the predetermined first angle from the x-axis as the respective second-type segments proceed from at or near one side of a BL (e.g., first BL) to at or near a side of the next BL (e.g., second BL) in the memory array.

At 910, a third-type segment of each of the respective WLs can be formed, where each third-type segment can be de-angled with respect to the respective second-type WL segment to proceed on a path parallel or substantially parallel to the x-axis. In one aspect, each of the respective third-type segments can be connected with respective second-type segments of the WLs. For instance, at or near a location on the side of the next BL (e.g., second BL), each third-type segment of respective WLs can be de-angled, with respect to the respective second-type WL segment connected therewith, such that the third-type segment can proceed along a path that can be parallel or substantially parallel to the x-axis. Each third-type segment can proceed across such next BL (e.g., second BL) in a direction parallel to the x-axis.

At 912, a fourth-type segment of each of the respective WLs can be formed, where each fourth-type segment can be angled at a predetermined second angle (e.g., negative angle between 0 and −90 degrees) from the x-axis based in part on the predetermined second angle. In one aspect, each respective fourth-type segment of respective WLs can be connected with respective third-type segments at a location that can be at or near the other side of the BL (e.g. second BL) that the third-type WL segment crossed and/or a storage element (e.g., 310) at or near such BL, and each respective fourth-type segment can extend at the predetermined second angle from the x-axis as the respective fourth-type segments proceed to a location at or near another BL (e.g., third BL) and/or storage element (e.g., 312) in the memory array.

At 914, a determination can be made as to whether the plurality of WLs are completed (e.g., are extended across the memory array). If it is determined that the plurality of WLs are not completed, methodology 900 can return to reference numeral 906, where additional WL segments (e.g., first-type segment(s), second-type segment(s), third-type segment(s), fourth-type segment(s)) can be formed, and methodology 900 can proceed until the plurality of WLs have been completely formed in the memory array. If, at 914, it is determined that the plurality of WLs are completely formed (e.g., extended across the memory array), methodology 900 can end.

In one aspect, methodology 900 can facilitate increasing the distance between storage elements (e.g., 310, 312) of the same memory cell (e.g., 306), where the increased distance between such storage elements can facilitate reducing complementary bit disturb and/or cross-talk noise between such storage elements, as compared to conventional memory arrays, such an orthogonal memory arrays, for example. For instance, conventionally, in an orthogonal memory array, two storage elements in a memory cell can be a distance d apart, where d can equal y.

The subject innovation, by employing methodology 900, for example, can facilitate increasing the distance between two storage elements (e.g., storage element 310 and storage element 312) of a memory cell (e.g., memory cell 306), by angling certain segments of the WL respectively associated with such storage elements so that one of the storage elements of the memory cell can be at one end of an angled segment of the WL and the other storage element of the memory cell can be at the other end of such angled segment of the WL, where the angling of the WL segment can facilitate increasing the distance between such storage elements based in part on the predetermined angle of the WL with respect to the WL segments to which the angled segment is connected. In one aspect, the predetermined angle of a particular angled WL segment can be between 0 and 90 degrees from the x-axis, or between 0 and −90 degrees. As a result of the angling of the WL segment, the distance d between the storage elements of the memory cell can be equal to y*F, where y can be the distance between two storage elements of a memory cell of a conventional memory array (e.g., with an orthogonal array) and F can be a real number that is greater than 1 and can be based in part on the angle between the angled WL segment and the WL segment to which the angled WL segment is connected and from which it is angling on a path in a different direction.

For example, in one embodiment, a WL segment between two adjacent storage elements can be angled at −45 degrees from the x-axis, and/or from a connected WL segment that is on a path parallel or substantially parallel to the x-axis. As a result of angling the WL segment, the distance d between two storage elements of a memory cell can be y*square root 2, where y can be the distance between two storage elements of a memory cell in a conventional memory array (e.g., with an orthogonal array).

It is to be appreciated that a memory array can comprise a plurality of sectors that each can contain a subset of the plurality of WLs. The WL spacing between a bottom WL of a sector and a top WL of another sector below the sector in the memory array can be the same distance or substantially the same distance as the distance between the respective WLs in a sector (e.g., the bottom WL in the sector and a WL adjacent to the WL in the sector).

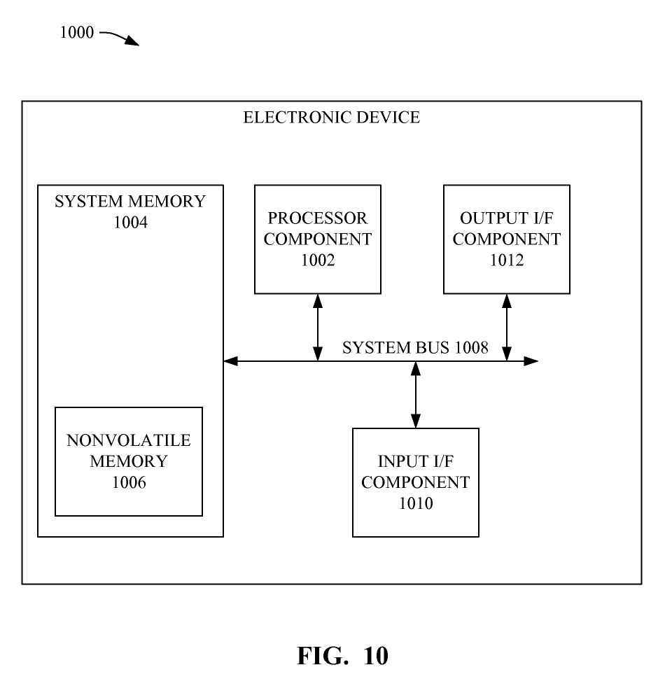

Referring to FIG. 10, illustrated is a block diagram of an exemplary, non-limiting electronic device 1000 that can comprise and/or incorporate memory device 100 and/or memory device 300, or a respective portion(s) thereof. The electronic device 1000 can include, but is not limited to, a computer, a laptop computer, network equipment (e.g., routers, access points), a media player and/or recorder (e.g., audio player and/or recorder, video player and/or recorder), a television, a smart card, a phone, a cellular phone, a smart phone, an electronic organizer, a PDA, a portable email reader, a digital camera, an electronic game (e.g., video game), an electronic device associated with digital rights management, a Personal Computer Memory Card International Association (PCMCIA) card, a trusted platform module (TPM), a Hardware Security Module (HSM), set-top boxes, a digital video recorder, a gaming console, a navigation system or device (e.g., global position satellite (GPS) system), a secure memory device with computational capabilities, a device with a tamper-resistant chip(s), an electronic device associated with an industrial control system, an embedded computer in a machine (e.g., an airplane, a copier, a motor vehicle, a microwave oven), and the like.

Components of the electronic device 1000 can include, but are not limited to, a processor component 1002, a system memory 1004, which can contain a nonvolatile memory 1006 (e.g., flash memory), and a system bus 1008 that can couple various system components including the system memory 1004 to the processor component 1002. The system bus 1008 can be any of several types of bus structures including a memory bus or memory controller, a peripheral bus, or a local bus using any of a variety of bus architectures.

Electronic device 1000 can typically include a variety of computer readable media. Computer readable media can be any available media that can be accessed by the electronic device 1000. By way of example, and not limitation, computer readable media can comprise computer storage media and communication media. Computer storage media includes volatile and non-volatile, removable and non-removable media implemented in any method or technology for storage of information such as computer readable instructions, data structures, program modules or other data. Computer storage media includes, but is not limited to, volatile memory and/or nonvolatile memory 1006, or other memory technology, CD-ROM, digital versatile disks (DVD) or other optical disk storage, magnetic cassettes, magnetic tape, magnetic disk storage or other magnetic storage devices, or any other medium which can be used to store the desired information and which can be accessed by electronic device 1000. Communication media typically embodies computer readable instructions, data structures, program modules or other data in a modulated data signal such as a carrier wave or other transport mechanism and includes any information delivery media.

The system memory 1004 can include computer storage media in the form of volatile (e.g., SRAM) and/or nonvolatile memory 1006 (e.g. flash memory). For example, the volatile memory (not shown) and/or nonvolatile memory 1006 can be the same or similar, or can contain the same or similar functionality, as memory device 100 (e.g., as illustrated in FIG. 1 and described herein) and/or memory device 300 (e.g., as illustrated in FIG. 1 and described herein). A basic input/output system (BIOS), containing the basic routines that can facilitate transferring information between elements within electronic device 1000, such as during start-up, can be stored in the system memory 1004. The system memory 1004 typically also can contain data and/or program modules that can be accessible to and/or presently be operated on by the processor component 1002. By way of example, and not limitation, the system memory 1004 can also include an operating system(s), application programs, other program modules, and program data.

The nonvolatile memory 1006 can be removable or non-removable. For example, the nonvolatile memory 1006 can be in the form of a removable memory card or a USB flash drive. In accordance with one aspect, the nonvolatile memory 1006 can include flash memory (e.g. single-bit flash memory, multi-bit flash memory), ROM, PROM, EPROM, EEPROM, or NVRAM (e.g., FeRAM), etc., or a combination thereof, for example. Further, a flash memory can comprise NOR flash memory and/or NAND flash memory.

A user can enter commands and information into the electronic device 1100 through input devices (not shown) such as a keypad, microphone, tablet, or touch screen although other input devices can also be utilized. These and other input devices can be connected to the processor component 1002 through input interface component 1010 that can be connected to the system bus 1008. Other interface and bus structures, such as a parallel port, game port or a universal serial bus (USB) can also be utilized. A graphics subsystem (not shown) can also be connected to the system bus 1008. A display device (not shown) can be also connected to the system bus 1008 via an interface, such as output interface component 1012, which can in turn communicate with video memory. In addition to a display, the electronic device 1000 can also include other peripheral output devices such as speakers (not shown), which can be connected through output interface component 1012.

It is to be understood and appreciated that the computer-implemented programs and software can be implemented within a standard computer architecture. While some aspects of the disclosure have been described above in the general context of computer-executable instructions that can be run on one or more computers, those skilled in the art will recognize that the technology also can be implemented in combination with other program modules and/or as a combination of hardware and software.

Generally, program modules include routines, programs, components, data structures, etc., that perform particular tasks or implement particular abstract data types. Moreover, those skilled in the art will appreciate that the inventive methods can be practiced with other computer system configurations, including single-processor or multiprocessor computer systems, minicomputers, mainframe computers, as well as personal computers, hand-held computing devices (e.g., PDA, phone), microprocessor-based or programmable consumer electronics, and the like, each of which can be operatively coupled to one or more associated devices.

The illustrated aspects of the disclosure may also be practiced in distributed computing environments where certain tasks are performed by remote processing devices that are linked through a communications network. In a distributed computing environment, program modules can be located in both local and remote memory storage devices.

It is also to be understood and appreciated that cryptographic protocols can be employed to facilitate security of data associated with a memory (e.g. memory device 100, memory device 300) in accordance with the disclosed subject matter. For example, a cryptographic component (e.g., cryptographic engine) can be employed and can facilitate encrypting and/or decrypting data to facilitate securing data being written to, stored in, and/or read from the memory. The cryptographic component can provide symmetric cryptographic tools and accelerators (e.g., Twofish, Blowfish, AES, TDES, IDEA, CAST5, RC4, etc.) to facilitate securing data. The cryptographic component can also provide asymmetric cryptographic accelerators and tools (e.g., RSA, Digital Signature Standard (DSS), and the like) to facilitate securing data. Additionally, the cryptographic component can provide accelerators and tools (e.g., Secure Hash Algorithm (SHA) and its variants such as, for example, SHA-0, SHA-1, SHA-224, SHA-256, SHA-384, and SHA-512) to facilitate securing data.

It is to be appreciated and understood that authentication protocols can be employed to facilitate security of data associated with the memory (e.g., memory device 100, memory device 300) in accordance with the disclosed subject matter. For example, an authentication component can solicit authentication data from an entity, and, upon the authentication data so solicited, can be employed, individually and/or in conjunction with information acquired and ascertained as a result of biometric modalities employed, to facilitate control access to the memory. The authentication data can be in the form of a password (e.g., a sequence of humanly cognizable characters), a pass phrase (e.g. a sequence of alphanumeric characters that can be similar to a typical password but is conventionally of greater length and contains non-humanly cognizable characters in addition to humanly cognizable characters), a pass code (e.g. Personal Identification Number (PIN)), and the like, for example. Additionally and/or alternatively, public key infrastructure (PKI) data can also be employed by the authentication component. PKI arrangements can provide for trusted third parties to vet, and affirm, entity identity through the use of public keys that typically can be certificates issued by the trusted third parties. Such arrangements can enable entities to be authenticated to each other, and to use information in certificates (e.g., public keys) and private keys, session keys, Traffic Encryption Keys (TEKs), cryptographic-system-specific keys, and/or other keys, to encrypt and decrypt messages communicated between entities.

The authentication component can implement one or more machine-implemented techniques to identify an entity by its unique physical and behavioral characteristics and attributes. Biometric modalities that can be employed can include, for example, face recognition wherein measurements of key points on an entity's face can provide a unique pattern that can be associated with the entity, iris recognition that measures from the outer edge towards the pupil the patterns associated with the colored part of the eye—the iris—to detect unique features associated with an entity's iris, and finger print identification that scans the corrugated ridges of skin that are non-continuous and form a pattern that can provide distinguishing features to identify an entity.

As utilized herein, terms “component,” “system,” “interface,” and the like, can refer to a computer-related entity, either hardware, software (e.g. in execution), and/or firmware. For example, a component can be a process running on a processor, a processor, an object, an executable, a program, and/or a computer. By way of illustration, both an application running on a server and the server can be a component. One or more components can reside within a process and a component can be localized on one computer and/or distributed between two or more computers.

Furthermore, the disclosed subject matter may be implemented as a method, apparatus, or article of manufacture using standard programming and/or engineering techniques to produce software, firmware, hardware, or any combination thereof to control a computer to implement the disclosed subject matter. The term “article of manufacture” as used herein is intended to encompass a computer program accessible from any computer-readable device, carrier, or media. For example, computer readable media can include but are not limited to magnetic storage devices (e.g., hard disk, floppy disk, magnetic strips . . . ), optical disks (e.g., compact disk (CD), digital versatile disk (DVD) . . . ), smart cards, and flash memory devices (e.g., card, stick, key drive . . . ). Additionally it should be appreciated that a carrier wave can be employed to carry computer-readable electronic data such as those used in transmitting and receiving electronic mail or in accessing a network such as the Internet or a local area network (LAN). Of course, those skilled in the art will recognize many modifications may be made to this configuration without departing from the scope or spirit of the disclosed subject matter.

Some portions of the detailed description have been presented in terms of algorithms and/or symbolic representations of operations on data bits within a computer memory. These algorithmic descriptions and/or representations are the means employed by those cognizant in the art to most effectively convey the substance of their work to others equally skilled. An algorithm is here, generally, conceived to be a self-consistent sequence of acts leading to a desired result. The acts are those requiring physical manipulations of physical quantities. Typically, though not necessarily, these quantities take the form of electrical and/or magnetic signals capable of being stored, transferred, combined, compared, and/or otherwise manipulated.

It has proven convenient at times, principally for reasons of common usage, to refer to these signals as bits, values, elements, symbols, characters, terms, numbers, or the like. It should be borne in mind, however, that all of these and similar terms are to be associated with the appropriate physical quantities and are merely convenient labels applied to these quantities. Unless specifically stated otherwise as apparent from the foregoing discussion, it is appreciated that throughout the disclosed subject matter, discussions utilizing terms such as processing, computing, calculating, determining, and/or displaying, and the like, refer to the action and processes of computer systems, and/or similar consumer and/or industrial electronic devices and/or machines, that manipulate and/or transform data represented as physical (electrical and/or electronic) quantities within the computer's and/or machine's registers and memories into other data similarly represented as physical quantities within the machine and/or computer system memories or registers or other such information storage, transmission and/or display devices.

What has been described above includes examples of aspects of the disclosed subject matter. It is, of course, not possible to describe every conceivable combination of components or methodologies for purposes of describing the disclosed subject matter, but one of ordinary skill in the art may recognize that many further combinations and permutations of the disclosed subject matter are possible. Accordingly, the disclosed subject matter is intended to embrace all such alterations, modifications and variations that fall within the spirit and scope of the appended claims. Furthermore, to the extent that the terms “includes,” “has,” or “having,” or variations thereof, are used in either the detailed description or the claims, such terms are intended to be inclusive in a manner similar to the term “comprising” as “comprising” is interpreted when employed as a transitional word in a claim.

What is claimed is:

1. A memory device, comprising:
at least one memory array that contains a plurality of wordlines, wherein each wordline has at least one segment that is angled based in part on a predetermined angle with respect to other wordline segments connected to the at least one segment to facilitate an increase in the distance between adjacent storage elements associated with the at least one segment; and
a plurality of memory cells included in the at least one memory array, wherein each memory cell contains at least one storage element that is associated with a respective wordline of the plurality of wordlines.

2. The device of claim 1, each wordline of the plurality of wordlines is formed in a zig-zag pattern of wordline segments that comprise at least one of a first type of wordline segment, a second type of wordline segment, a third type of wordline segment, or a fourth type of wordline segment, or a combination thereof, wherein the first type of wordline segment is formed on a path parallel to an x-axis, the second type of wordline segment is connected with a first type of wordline segment and is formed on a path in an xy-direction based in part on a predetermined positive angle with respect to the x-axis, a third type of wordline segment is connected with a second type of wordline segment and is formed as another path parallel to the x-axis, and a fourth type of wordline segment is connected with a third type of wordline segment and is formed in a path in another xy-direction based in part on a predetermined negative angle with respect to the x-axis.

3. The device of claim 1, the predetermined angle has a value between 0 and 90 degrees, or between 0 and −90 degrees, with respect to an x-axis.

4. The device of claim 1, the predetermined angle associated with the at least one segment is at least one of 45 degrees or 45 degrees, or a combination thereof, with respect to an x-axis.

5. The device of claim 1, further comprising a plurality of bitlines that are each formed in a substantially straight path that is parallel to a y-axis, wherein respective memory cells are formed at a crossing point of a respective bitline and a respective wordline.

6. The device of claim 1, each memory cell of the plurality of memory cells contains two adjacent storage elements that are at respective ends of a wordline segment that is angled based in part on the predetermined angle with respect to other wordline segments connected to such wordline segment.

7. The device of claim 1, wherein at least one storage element of a memory cell of the plurality of memory cells is adjacent to at least one storage element of an adjacent memory cell and are at respective ends of a wordline segment that is angled based in part on the predetermined angle with respect to other wordline segments connected to such wordline segment.

8. The device of claim 1, the at least one memory array further comprising a plurality of sectors that each contain a respective plurality of wordlines, wherein the plurality of wordlines are each formed in a zig-zag formation and a bottom wordline of a sector above and adjacent to another sector in the at least one memory array is spaced at substantially the same distance from a top wordline of the other sector as the space between the bottom wordline of the sector and a wordline adjacent to the bottom wordline within the sector.

9. The device of claim 1, the distance between the two adjacent storage elements is increased by a factor based in part on the predetermined angle associated with the at least one segment of a wordline, wherein the factor is a real number greater than one.

10. The device of claim 1, wherein the at least one memory device comprises at least one of nonvolatile memory or volatile memory, or a combination thereof.

11. The device of claim 1, wherein the at least one memory device comprises at least one or more of read-only memory, flash memory, mask-programmed read-only memory, programmable read-only memory, erasable programmable read-only memory, Ultra Violet (UV)-erase erasable programmable read-only memory, one-time programmable read-only memory, electrically erasable programmable read-only memory, phase change memory, nonvolatile random access memory, random access memory, static random access memory, dynamic random access memory, synchronous dynamic random access memory, double data rate synchronous dynamic random access memory, enhanced synchronous dynamic random access memory, Synchlink dynamic random access memory, Rambus direct random access memory, direct Rambus dynamic random access memory, or Rambus dynamic RAM random access memory, or a combination thereof.

12. An electronic device comprising the memory device of claim 1.

13. The electronic device of claim 12, the electronic device is one of a computer, a cellular phone, a digital phone, a video device, a smart card, a personal digital assistant, a television, an electronic game, a digital camera, an electronic organizer, an audio player, an audio recorder, an electronic device associated with digital rights management, a Personal Computer Memory Card International Association (PCMCIA) card, a trusted platform module (TPM), an electronic control unit associated with a motor vehicle, a global positioning satellite (GPS) device, an electronic device associated with an airplane, an electronic device associated with an industrial control system, a Hardware Security Module (HSM), a set-top box, a secure memory device with computational capabilities, or an electronic device with at least one tamper-resistant chip.

14. A method that facilitates data storage in a memory device, comprising:
angling at least one segment of a wordline associated with at least two adjacent storage elements based in part on a predetermined angle associated with the at least one segment to facilitate increasing the distance between the at least two adjacent storage elements; and
forming the at least two adjacent storage elements, wherein a storage element is formed at one end of the at least one segment and an adjacent storage element is formed at another end of the at least one segment.

15. The method of claim 14, further comprising:
forming at least two storage elements at a predetermined distance apart based in part on the predetermined angle associated with the at least one segment of the wordline, the at least two storage elements are adjacent to each other along the wordline and each storage element belongs to a respectively memory cell;
forming a plurality of bitlines; and
forming a plurality of wordlines, comprising:
forming a first-type segment of a respective wordline that has a path that is substantially parallel to an x-axis, and
forming a second-type segment of the respective wordline that is angled at a predetermined first angle from the x-axis based in part on the predetermined first angle, the second-type segment is connected to a first-type segment.

16. The method of claim 15, forming the plurality of wordlines, further comprising:
forming a third-type segment of the respective wordline that has a path that is substantially parallel to the x-axis, the third-type segment is connected to a second-type segment; and
forming a fourth-type segment of the respective wordline that is angled at a predetermined second angle from the x-axis based in part on the predetermined second angle, the fourth-type segment is connected to a third-type segment.

17. The method of claim 14, further comprising:
forming at least two storage elements at a predetermined distance apart based in part on the predetermined angle associated with the at least one segment of the wordline, the at least two storage elements are adjacent to each other in a memory cell associated with the wordline;
forming a plurality of bitlines; and
forming a plurality of wordlines, comprising:
forming a first-type segment of a respective wordline that has a path that is substantially parallel to an x-axis, and
forming a second-type segment of the respective wordline that is angled at a predetermined first angle from the x-axis based in part on the predetermined first angle, the second-type segment is connected to a first-type segment.

18. The method of claim 17, further comprising:
forming a third-type segment of the respective wordline that has a path that is substantially parallel to the x-axis, the third-type segment is connected to a second-type segment; and
forming a fourth-type segment of the respective wordline that is angled at a predetermined second angle from the x-axis based in part on the predetermined second angle, the fourth-type segment is connected to a third-type segment.

19. The method of claim 18, the first predetermined angle is between 0 degrees and 90 degrees, and the second predetermined angle is between 0 degrees and −90 degrees.

20. The method of claim 14, further comprising:
forming a plurality of sectors, wherein each sector of the plurality of sectors is comprised of a subset of wordlines, and wherein the spacing between a bottom wordline of a sector and a top wordline of another sector below the sector in the memory array is substantially equivalent to the spacing between the bottom wordline of the sector and another wordline adjacent to the bottom wordline in the sector.
